(19) United States
(12) Patent Application Publication
(10) Pub. No.: US 2010/0006142 A1
(43) Pub. Date: Jan. 14, 2010

(54) Deposition apparatus for improving the uniformity of material processed over a substrate and method of using the apparatus

(75) Inventors: Yang Li, Troy, MI (US); Scott Jones, Romeo, MI (US); Vin Cannella, Beverly Hills, MI (US); Arun Kumar, Ann Arbor, MI (US); Joachim Doehler, White Lake, MI (US); Kais Younan, Rochester Hills, MI (US)

Correspondence Address: ENERGY CONVERSION DEVICES, INC., 2956 WATERVIEW DRIVE, ROCHESTER HILLS, MI, 48309, US

(73) Assignee: United Solar Ovonic LLC

(21) Appl. No.: 12/460,061

(22) Filed: Jul. 13, 2009

Related U.S. Application Data
(60) Provisional application No. 61/134,855, filed on Jul. 14, 2008.

(51) Int. Cl. H01L 31/0248; C23C 16/00; C23C 14/34; C25B 9/00; H01L 21/306; H05H 1/24

(52) U.S. Cl. 136/252; 118/715; 204/298.02; 204/298.23; 204/298.31; 156/345.1; 427/569; 204/192.12; 204/192.32; 216/71

(57) ABSTRACT

Deposition apparatus for uniformly forming material on a substrate in accordance with an exemplary embodiment is provided. The deposition apparatus includes an energy source, an electrode in a facing, spaced relationship with respect to the substrate, and interface structure joined to the electrode. The interface structure is configured to electrically couple energy from the energy source through and about the interface structure to the electrode for formation of a substantially uniform electric field between the electrode and a predetermined area of the substrate when the interface structure is supplied with energy from the energy source.

### CROSS-REFERENCE TO RELATED APPLICATIONS

The present invention relates to, and is entitled to the benefit of the earlier filing date and priority of, U.S. Provisional Patent Application No. 61/134855, filed Jul. 14, 2008, the disclosure of which is hereby incorporated by reference.

### GOVERNMENT INTEREST

This invention was made, at least in part, under U.S. Government, Department of Energy, Contract No. DE-FC36-07G017053. The Government may have rights in this invention.

### FIELD OF THE INVENTION

This invention relates generally to processing material over substrates. More particularly, the invention relates to apparatus for the formation of material over a substrate where the apparatus is configured for forming a substantially uniform electric field, wherein energized materials within the uniform electric field are processed over the substrate in a substantially uniform manner.

### BACKGROUND OF THE INVENTION

Deposition apparatus have been widely used for manufacturing semiconductor devices such as photoresponsive devices, thin-film transistors, integrated circuits, device arrays, displays, and the like.

In many applications, deposition apparatus includes a chamber having therein an electrode and a substrate or web of material that is to have material processed over a predetermined portion of the substrate. Process gases are introduced into the chamber for a variety of purposes related to the processing of the materials over the substrate. In processing applications, for example where materials are deposited over the substrate, the process gases may include deposition precursors, such as doping precursors, and carrier gases such as inert or diluent gases, which may or may not be incorporated into material deposited on the substrate. An energy source provides energy to the electrode to form an electric and magnetic field in a region of the electrode and the substrate. For example, energy sources utilized are AC or DC energy, or energy in the radio frequency (RF), VHF or microwave range.

In a plasma-assisted deposition process such as a glow-discharge process, the electric field energizes the process gases to form plasma in a region of the electrode and the substrate, called a plasma region or an activation region. Under the influence of the electric field, the process gases experience multiple collisions between free electrons and gas molecules to generate a plurality of reactive species such as ions and neutral radicals. The plasma kinetics producing the reactive species includes fragmentation, ionization, excitation and recombination of the process gas mixture.

The distribution of various reactive species is also influenced by the electron temperature, electron density and the duration of multiple electron collisions when exposed to the energy of the electric and magnetic fields. In order for the plasma to be self-sustaining, the electrons must have sufficient energy to generate the collisions. Since the uniformity and quality of a deposited material or film correlates with the distribution of reactive species within the plasma, it follows that generating a substantially uniform energy or electric field to activate or energize the process gases in a uniform manner is one of the goals in the plasma-assisted deposition process.

Distribution of the energy from the energy source to the electrode influences the uniformity of the electric field about the electrode. In one approach, for example a parallel-plate electrode configuration, the energy is provided to the electrode at a single location at a side of the electrode, for example, via a coaxial cable coupled to the electrode. In that approach, the energy may not distribute about the electrode in a uniform manner due to a variety of reasons such as the presence of standing-waves or stray capacitance, thus forming a non-uniform electric field about the electrode. Therefore, the non-uniform electric field does not energize the process gases in a uniform manner and the plasma is not likely to have a uniform distribution of materials therein. Therefore, it is less likely that desirable materials of the plasma will be processed over the substrate in a uniform manner.

In another approach, energy is provided to the electrode at multiple locations. The resulting electric field formed about the electrode may have perturbations for a variety of reasons, for example, due to energy wave reflections from boundary conditions of the electrode. Additional controls are sometimes utilized to minimize the perturbations in the electric field, for example by using voltage and/or phase modulation with the applied energy for smoothing out the distribution of the electric field about the electrode, a more complicated approach.

Accordingly, the inventors herein seeking deposition apparatus to improve the uniformity of material processed over a substrate have recognized a need for apparatus that contributes to directing energy from an energy source to an electrode in a manner that promotes the formation of a substantially uniform electric field about the electrode.

### SUMMARY OF THE INVENTION

Deposition apparatus for uniformly forming material on a substrate in accordance with an exemplary embodiment is provided. The deposition apparatus includes an energy source, an electrode in a facing, spaced relationship with respect to the substrate, and interface structure joined to the electrode. The interface structure is configured to electrically couple energy from the energy source through and about the interface structure to the electrode for formation of a substantially uniform electric field between the electrode and a predetermined area of the substrate when the interface structure is supplied with energy from the energy source.

Deposition apparatus for uniformly forming material on a substrate in accordance with another exemplary embodiment is provided. The deposition apparatus includes an energy source, a plurality of substrates, an electrode, interface structure, a reaction chamber, and apparatus configured to distribute the inlet of gaseous materials into the reaction chamber and the outlet of gaseous materials from the reaction chamber.

The plurality of substrates includes a first substrate and a second substrate in a facing, spaced relationship with respect to each other. The electrode is positioned between the first and the second substrate. The electrode is in a facing, spaced relationship with respect to both the first and the second substrates. The interface structure is joined to the electrode and the interface structure is configured to electrically couple energy from the energy source through and about the interface structure to the electrode for the formation of a substantially uniform electric field between the electrode and a predetermined area of the first substrate and between the electrode and a predetermined area of the second substrate when the interface structure is supplied with energy from the energy source. The reaction chamber is configured to receive the first and second substrates, the electrode and the interface structure therein.

A method of processing material over a substrate in accordance with another exemplary embodiment is provided. The method includes providing a reaction chamber, an electrode facing and spaced apart from the substrate, an interface structure joined to the electrode; and an energy source, the reaction chamber configured to receive the substrate, the electrode and the interface structure therein, and the interface structure being configured to electrically couple energy from the energy source through and about the interface structure to the electrode for the formation of a substantially uniform electric field between the electrode and a predetermined area of the substrate when energy from the energy source is supplied to the interface structure.

The method further includes supplying a gas into the reaction chamber. The method further includes setting a pressure within the reaction chamber at a vacuum pressure. The method further includes supplying energy from the energy source to the interface structure. The method further includes forming a plasma within the substantially uniform electric field, wherein a material of the plasma is deposited on the substrate.

### BRIEF DESCRIPTION OF THE DRAWINGS

FIG. 1 is an isometric view of deposition apparatus illustrating a configuration for electrically coupling energy to an electrode;

FIG. 2 is a plot of a simulated electric field across the electrode of FIG. 1;

FIG. 3 is an isometric view of deposition apparatus having an electrode and interface structure joined to the electrode in accordance with an exemplary embodiment of the invention;

FIG. 4 is a plot of a simulated electric field across the electrode of FIG. 3;

FIG. 5 is a plot of silicon deposition comparing the normalized and integrated deposited film thicknesses over substrates used with the deposition apparatus of FIGS. 1 and 3;

FIG. 6 is a plot of silicon-germanium deposition comparing the normalized and integrated deposited film thicknesses over substrates used with the deposition apparatus of FIGS. 1 and 3;

FIG. 7 is a configuration of deposition apparatus having interface structure joined to an electrode in accordance with an alternative exemplary embodiment;

FIG. 8 is a plot of a simulated electric field across the electrode of FIG. 7;

FIG. 9 is a plot of silicon deposition over a substrate used with the deposition apparatus of FIG. 7;

FIG. 10 is an alternative configuration of interface structure in accordance with another exemplary embodiment;

FIG. 11 is an exploded isometric view of a configuration of deposition apparatus in accordance with another alternative exemplary embodiment;

FIG. 12 is plan view of the deposition apparatus of FIG. 11;

FIG. 13 is a cross section view of the deposition apparatus of FIG. 11 taken along lines 13-13; and

FIGS. 14 and 15 are other configurations deposition apparatus in accordance with additional alternative exemplary embodiments of this disclosure.

### DETAILED DESCRIPTION OF THE INVENTION

Disclosed herein are exemplary embodiments of deposition apparatus configured for improving the uniformity of an electric field formed about an electrode in a region between the electrode and a substrate spaced apart from the electrode, to aid in processing material uniformly over the substrate. Embodiments of the apparatus include configurations of structure joined with an electrode and electrically coupled with an energy source. Exemplary embodiments of the structure disclosed herein are configured to electrically couple energy from the energy source through and about the structure to the electrode in a manner for the formation of a substantially uniform electric field about the electrode proximate one or more substrates.

The exemplary embodiments of deposition apparatus disclosed herein are not limited to horizontal or vertical orientations, or parallel-plate configurations. The deposition apparatus configuration will be suitable for the manufacturing process of the particular semiconductor device, the process involved, the process gases involved, and/or other process parameters. Additionally, the substrates contemplated for use with the exemplary embodiments of deposition apparatus are conducting materials including composite compositions including those containing metal and polymers. Depending on the application, the deposition apparatus will be arranged with respect to a substrate so that a predetermined area of the substrate, within the uniform electric field, is spaced apart from the electrode from approximately 0.10 inches to approximately 3.00 inches.

Additionally, the exemplary embodiments of the disposition apparatus disclosed hereinbelow may include an electrode having gas distribution means integral with the electrode structure. For example, the electrode structure may include therein a gas distribution manifold where a process gas within the manifold is directed toward the plasma region through a plurality of pores of one or more outer surfaces of the electrode structure. This example of routing process gases through an electrode or cathode is described in U.S. patent application Ser. No. 10/043,010, entitled “Fountain Cathode for Large Area Plasma Deposition; and U.S. patent application Ser. No. 11/447,363, entitled “Pore Cathode for the Mass Production of Photovoltaic Devices Having Increased Conversion Efficiency,” the disclosures of which are incorporated herein by reference.

The resulting substantially uniform electric field energizes process gases proximate the substrate to form plasma, wherein desirable materials of the plasma are processed over the substrate during a manufacturing process, for example during a plasma-assisted deposition process in forming a layer or a film of a semiconductor device. Enhancing the uniformity of the electric field aids in formation of uniform plasma and increases the uniformity of materials processed over the substrate.

As used herein, “electrically coupled” refers to a relationship between structures that allows energy to flow at least partially between the structures. This definition is intended to apply to portions of structures in physical contact and to portions of structures that are not in physical contact. Generally, two structures or materials which are electrically coupled can have an electrical potential or current between the two structures such that energy, including electric fields and magnetic fields, can flow through and/or about one structure to the other structure. For example, two structures are considered electrically coupled where energy transfers between the structures resistively and capacitively along a substantial dimension of one of the structures proximate the interface of the structures. In another example, the energy transfers between the structures resistively, capacitively, and includes inductively distributive coupling along a substantial dimension of one of the structures proximate the interface of the structures. In exemplary embodiments described herein, interface structure is configured so electric coupling aids in the formation of a substantially uniform electric field about a predetermined area of an electrode spaced apart from one or more substrates spaced apart from the electrode.

For example, energy is electrically coupled, between an electrode and an embodiment of interface structure joined to an electrode, along a dimension of the electrode that is greater than 30% of the length of the electrode proximate the interface structure. In another example, energy is electrically coupled, between an electrode and an embodiment of interface structure joined to an electrode, along a dimension of the electrode that is approximately 50% of the length of the electrode proximate the interface structure. In another example, energy is electrically coupled, between an electrode and an embodiment of interface structure joined to an electrode, along a dimension of the electrode that is approximately 75% of the length of the electrode proximate the interface structure. In another example, energy is electrically coupled between an electrode and an embodiment of interface structure joined to an electrode along a dimension of the electrode that is greater than 90% of the length of the electrode proximate the interface structure. In another example, two structures that are not physically joined together are still considered electrically coupled when the structures are separated by a dielectric material (such as air) and supplied with an alternating current source (energy source) so that electric current flows between the structures by capacitive means.

Embodiments of the deposition apparatus described herein, and modifications thereto readily apparent to those skilled in the art, are contemplated to be applicable in the processing/formation of semiconductor devices, for example, photoresponsive devices such as photovoltaic devices, thin-film transistors, integrated circuits, device arrays, displays, as well as for applications for etching portions of semiconductor devices.

Exemplary embodiments of the deposition apparatus disclosed herein include interface structure joined to an electrode and electrically coupled to an energy source, wherein the interface structure includes a plurality of different regions and at least two of the regions at least partially overlap one another. The interface structure is configured to electrically couple the energy from the energy source through and about the interface structure to the electrode in a manner to aid in the formation of a substantially uniform electric field about a predetermined region between a surface of the electrode and a substrate spaced apart from the electrode.

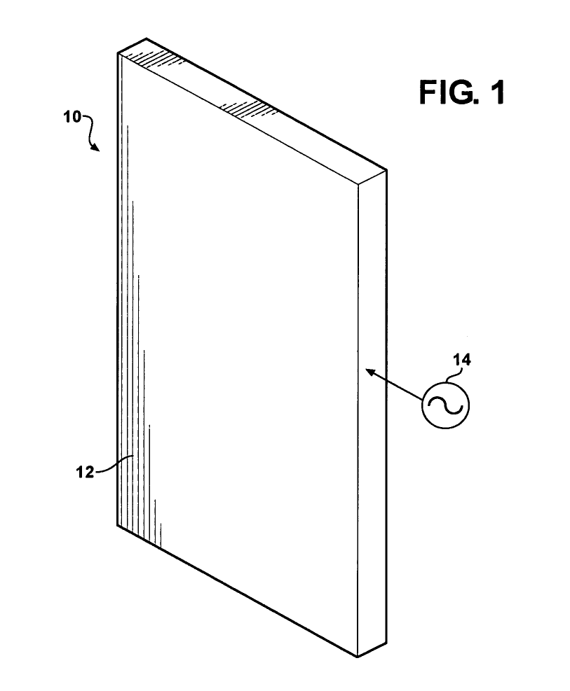

Referring to FIG. 1, an example of a configuration of deposition apparatus 10 is presented for simulation of a non-uniform electric field. Deposition apparatus 10 is presented for comparison purposes with exemplary embodiments of deposition apparatus configured to generate a substantially uniform electric field discussed hereinbelow.

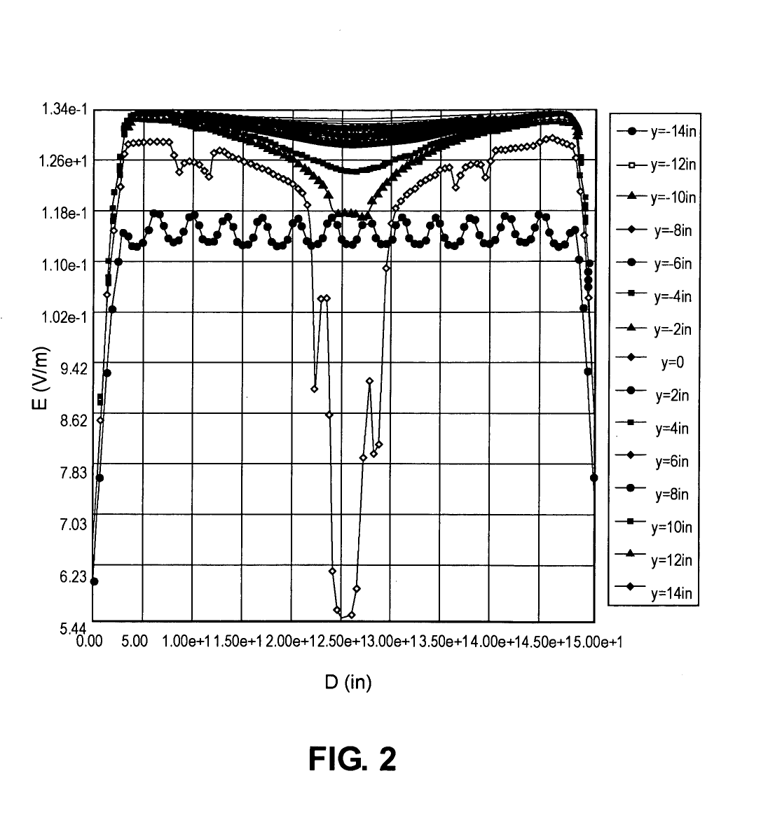

Deposition apparatus 10 includes a rectangular electrode 12 and an energy input 14 electrically coupled to the electrode. In this instance, energy input 14 is RF power with a value of approximately 13.56 MHz electrically coupled at the approximate mid-length location of one of the longer sides of the electrode. FIG. 2 illustrates the simulation of an electric field over a surface of the electrode 12 upon the activation of the energy input. The electric field intensity is clearly not uniform over the surface of the electrode and the electric field intensity sharply decreases about the electrode surface along the mid-region of the electrode proximate D=25.0 in. This region of reduced electric field intensity corresponds with the location of the energy input, illustrated in FIG. 2 along the longer side of the electrode corresponding to Y=−14 in. and D=25.0 in.

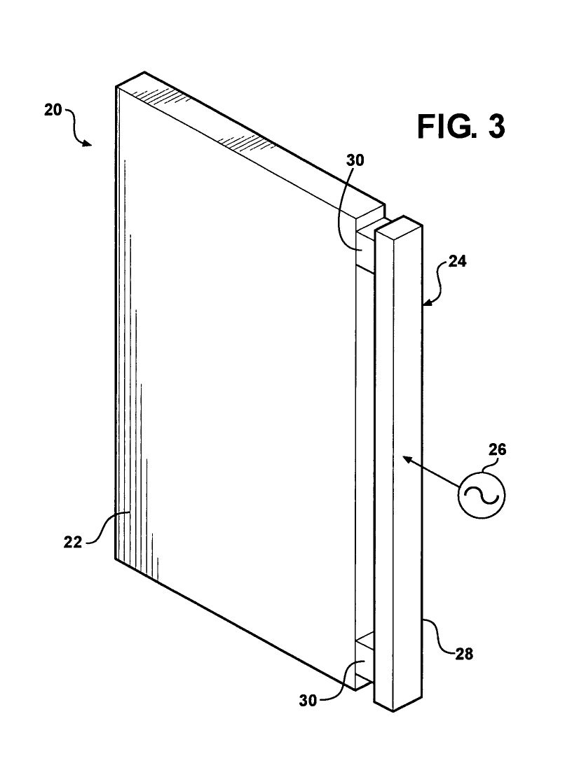

Referring to FIG. 3, a configuration of deposition apparatus 20 for simulation of a uniform electric field is illustrated in accordance with an exemplary embodiment of the invention. Deposition apparatus 20 includes an electrode 22, interface structure 24, and an energy input 26 electrically coupled to the interface structure.

In this embodiment, the interface structure 24 includes a bar 28 and two spacers 30 joined to the electrode 22. The spacers 30 are configured to space the bar 28 a predetermined distance from the electrode 22. In this embodiment, the two different regions of the interface structure are the bar and the space or slot between the electrode and the bar when the interface structure is joined to the electrode. Here, the two different regions overlap each other along a substantial length of the electrode side the interface structure is joined to. In an alternative embodiment, the above interface structure could be a solid bar with a slot/recessed portion formed therein creating a channel-shaped member. The interface structure 24 is arranged and configured to electrically couple the energy from energy input 26 through and about the interface structure to the electrode in a manner to form a substantially uniform electric field about a predetermined region between a surface of the electrode and a substrate spaced apart from the electrode.

In particular, the interface structure is configured direct a portion of the input energy toward portions of the electrode distal the location of energy input at the interface structure. In this embodiment, the energy is directed by the interface structure toward the comers of the electrode. During processing, the substrate is positioned with respect to the electrode so that a predetermined area of the substrate surface corresponds with the predetermined region of the uniform electric field about the electrode.

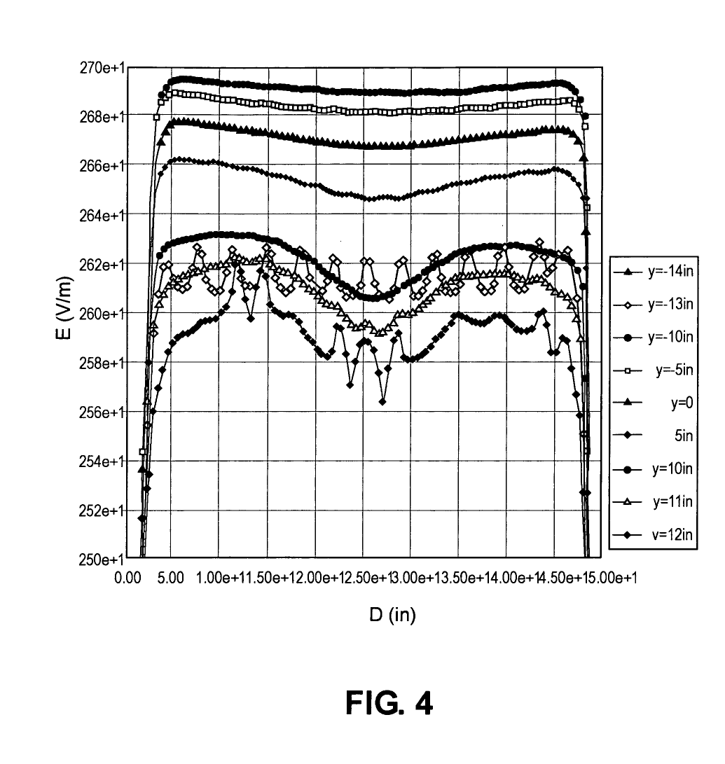

The energy input 26 is RF power with a value of approximately 13.56 MHz electrically coupled to the mid-length location of one of the longer sides of the electrode. FIG. 4 illustrates the simulation of an electric field over a surface of the electrode 22 upon activation of the energy input 26 at Y=−14 in. and D=25.0 in. of FIG. 4. The electric field is clearly more uniform over the surface of the electrode and does not exhibit the dramatic decrease in electric field intensity near the location of the energy input compared with the electric field distribution illustrated in FIG. 2 for the deposition apparatus 10 of FIG. 1.

Deposition tests were performed to determine if the location of simulated non-uniform electric field (FIG. 2) about the electrode produced similar non-uniformity for material deposited over a substrate spaced apart from the electrode using actual deposition apparatus corresponding to the simulated apparatus of FIG. 1 without interface structure. Deposition tests were also performed to determine if the location of simulated uniform electric field (FIG. 4) about the electrode produced similar uniformity for material deposited over a substrate spaced apart from the electrode using actual deposition apparatus corresponding to the simulated apparatus of FIG. 3 that includes interface structure. The electrodes and interface structure of the constructed deposition apparatus and the substrates included a conductive material such as steel, aluminum and the like.

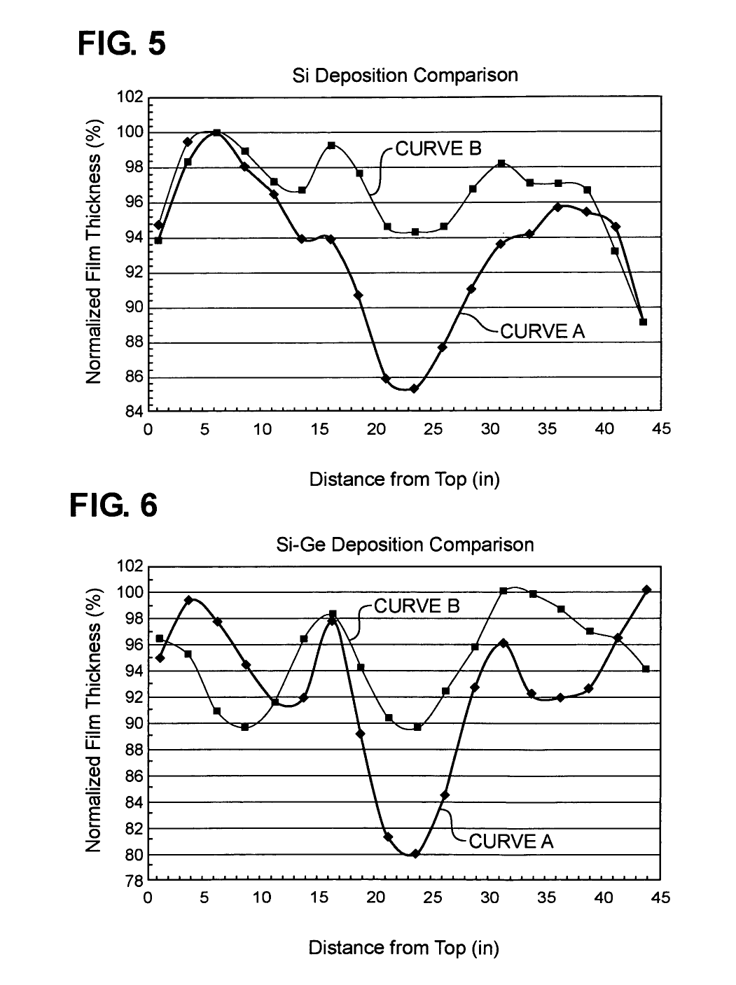

FIG. 5 illustrates silicon (Si) deposited film thickness variation over substrates for deposition apparatus that does not include interface structure, as shown in curve A, compared with deposition apparatus that includes interface structure, as shown in curve B. The energy input, approximately 13.56 MHz, was electrically coupled to the electrode in the case where interface structure was not used, and electrically coupled to the interface structure where interface structure was used, as discussed hereinabove. The deposited Si film thickness is integrated and normalized across the substrate and plotted along the lengthwise direction of the substrate. Curve A shows a substantial decrease in deposited Si film thickness uniformity proximate the location of the energy input near 21 in. This decrease in Si film thickness uniformity near the location of energy input to the electrode corresponds with the decrease in simulated electric field intensity at the location of energy input of FIG. 2 for deposition apparatus where the energy input electrically couples to the electrode without the use of the interface structure. Curve B shows an improved Si film thickness uniformity over the substrate and corresponds with the improved simulated electric field uniformity of FIG. 4 for deposition apparatus where the energy input electrically couples to the electrode with the use of the interface structure 24 of FIG. 3.

FIG. 6 similarly illustrates silicon-germanium (Si—Ge) deposited film thickness variation over substrates for deposition apparatus that does not include interface structure, as shown in curve A, compared with deposition apparatus that includes interface structure, as shown in curve B. As with the depositions illustrated in FIG. 5, the energy input, approximately 13.56 MHz, was electrically coupled to the electrode in the case where interface structure was not used, and electrically coupled to the interface structure where interface structure was used, as discussed hereinabove. Curve A corresponds with the Si film thickness non-uniformity of FIG. 5 where the energy input electrically couples to the electrode without the use of the interface structure. Curve B shows an improved Si—Ge film thickness uniformity over the substrate and corresponds with the improved Si film thickness uniformity of FIG. 5 for deposition apparatus where the energy input electrically couples to the electrode with the use of the interface structure 24.

The deposition tests confirm that incorporation of a configuration of interface structure improves the electric field uniformity in a region between the electrode and the substrate and the improved electric field uniformity in turn contributes to formation of substantially uniform plasma in the plasma region for depositing desirable materials of the plasma over a predetermined area of the substrate. In the deposition tests, the improved electric field uniformity contributes to improved deposited film thickness uniformity over the substrate. And in some unique embodiments of interface structure, the uniformity of deposited material is substantially improved in particular at a region of the substrate corresponding with a single location of energy input electrically coupled with the interface structure, such as is illustrated in FIGS. 5 and 6 for interface structure 24.

This shows that the interface structure improves the electric coupling of the energy input with the electrode in a manner that improves the electric field uniformity about the electrode in the region of energy input. Embodiments of interface structure contemplated also contribute to improving the uniformity of the formed electric field and the uniformity of material deposited over a predetermined area of the substrate other than proximate the location of energy input.

While the deposition tests illustrate improved deposited film thickness uniformity, it is contemplated that a more uniform plasma will also contribute to improving other aspects of processing material from the plasma over the substrate such as quality of the film in terms of film homogeneity and properties such as optical, electrical, chemical, defect density, etc. It is also contemplated that having the capability for generating a substantially uniform electric field to aid in forming a substantially uniform plasma can be utilized for other processes such as plasma-assisted etching of material over a substrate.

The interface structure of FIG. 3 is configured to promote formation of a substantially uniform electric field and magnetic field about the electrode in a predetermined region between the electrode and the substrate upon activation of the energy source. The configuration of the interface structure, including the space/slot/recess width, length and cross section, also depends on the particular configuration of the semiconductor device being formed including its shape and materials, the configuration of the electrode, the number of substrates positioned about the electrode for processing, stationary vs. moving substrate(s), the process involved, process gases involved, process pressure and temperature, and/or other process parameters.

In exemplary embodiments of the deposition apparatus and depending on the application, the space/slot dimension between the bar and the electrode will range up to approximately 10× a cross sectional thickness of the bar to provide substantial electrical coupling between the interface structure and the electrode. In non-limiting examples, the space/slot dimension is approximately 1.5×, 2×, 3.6×, 4×, 5×, etc. a cross sectional thickness of the bar for the formation an improved uniform distribution of electric field in a predetermined region between the electrode and the substrate. Alternative embodiments of the interface structure include solid or partially solid members, and composite structure where the plurality of different regions are made of different material configured to promote the formation of the uniform electric field about the electrode. Additionally, the configuration of the interface structure may vary in the orthogonal direction with respect to the substantially planar electrode surfaces shown in FIG. 3. The configuration of the interface structure may vary in the orthogonal direction to suit a particular electrode configuration and/or to promote the formation of the uniform electric field about the electrode.

In an alternative embodiment, the electrode of the deposition apparatus is configured so that the interface structure is an integral portion of the electrode. For instance, the electrode can be machined to form an elongated hole or slot proximate an edge of the electrode. The slot width and length thus formed from the electrode create the interface structure, i.e. the slot and the bar adjacent the slot. In another alternative embodiment, a cross section of the slot is not constant along the slot length. For example, the slot can be tapered along its length. In one embodiment, the interface structure material is the same as the electrode material. In another embodiment, the interface structure includes a combination of materials that may or may not be the same as the electrode material configuration. In another embodiment, the slot can have a material therein different compared to the electrode and bar material. In another alternative embodiment of the deposition apparatus, the electrode can include a shaped portion to further improve the uniformity of the electric field about a surface of the electrode. For example, the end of the electrode opposite the interface structure may include a tapered section across the thickness of the electrode to improve the uniformity of the electric field.

In some alternative embodiments, the interface structure includes a plurality of members spaced apart from each other and arranged in an overlapping manner with respect to each other along a surface of the electrode. In exemplary embodiments of interface structure and depending on an application, the space/slot dimension between the members and between the members spaced along side the electrode will range from up to 10× a cross sectional thickness of a member along side the slot or a member spaced apart from another member to provide substantial electric coupling between the interface structure and the electrode. Non-limiting examples of the space/slot dimension include 1.5×, 2×, 3.6×, 4×, 5×, etc. a cross sectional thickness of a adjacent member of the interface structure. The spacing may or may not be uniform depending on the configuration of the interface structure, the electrode and the desired region of formation of uniform electric field, etc. For instance, in one exemplary embodiment the interface structure includes a first plurality of spaced apart members joined to a side of an electrode where a portion of each member is also spaced apart from the electrode. The interface structure further includes at least a second plurality of spaced apart members where a portion of each member is joined to a plurality of members that are joined to the electrode and each of the second plurality of members also at least partially overlap at least one of the members that are joined to the electrode. In other embodiments, a configuration of interface structure may include more than two sets of spaced apart members arranged in an overlapping arrangement with respect to each other as they extending in a direction away from the side of the electrode.

The interface structure configuration may be influenced by the electrode configuration including its material, size and shape, energy source types and levels, substrate configuration such as material, size and shape, other processing parameters, and combinations thereof. It is contemplated that the deposition apparatus of FIG. 3, or an alternative embodiment apparent to those skilled in the art, can be utilized for processing material, such as depositing material by plasma-assisted deposition, over a predetermined substrate area 50 inches by 30 inches or less via, for example, the application of RF or VHF energy to the interface structure. In other embodiments, the predetermined substrate area is larger say for example up to 10,000 in² and not limited to geometric shapes such as squares or rectangles, etc.

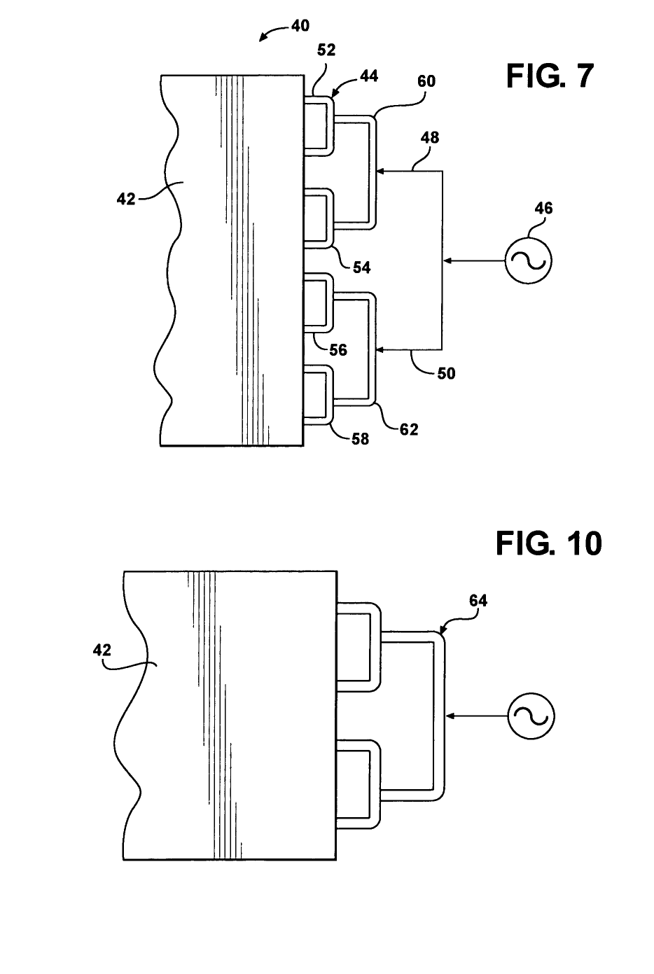

Referring to FIG. 7, deposition apparatus 40 in accordance with another exemplary embodiment is illustrated. Deposition apparatus 40 includes an electrode 42, interface structure 44 joined to the electrode and energy input 46 routed, e.g. via electrical cable, to feed energy at two locations 48, 50 at the interface structure.

The interface structure 44 includes a plurality of bars 52, 54, 56, and 58 each of which includes a portion joined to the electrode and a portion spaced apart from the electrode. Each of the bars 52, 54, 56, and 58 is further spaced apart from one another along the electrode. The interface structure 44 further includes another plurality of bars 60 and 62. Bar 60 is joined to bars 52, 54 and includes a portion that is spaced apart from bars 52, 54 extending in a direction away from the electrode. Bar 62 is joined to bars 56, 58 and includes a portion that is spaced apart from bars 56, 58 extending in a direction away from the electrode. In this example, bar 60 at least partially overlaps bars 52, 54 and bar 62 at least partially overlaps bars 56, 58.

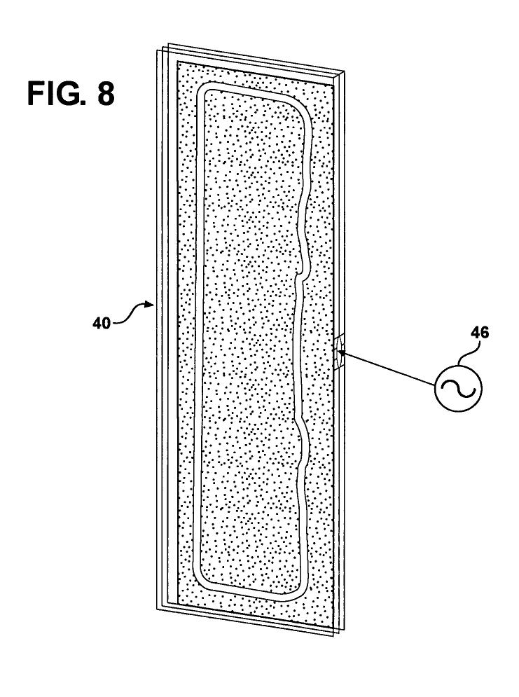

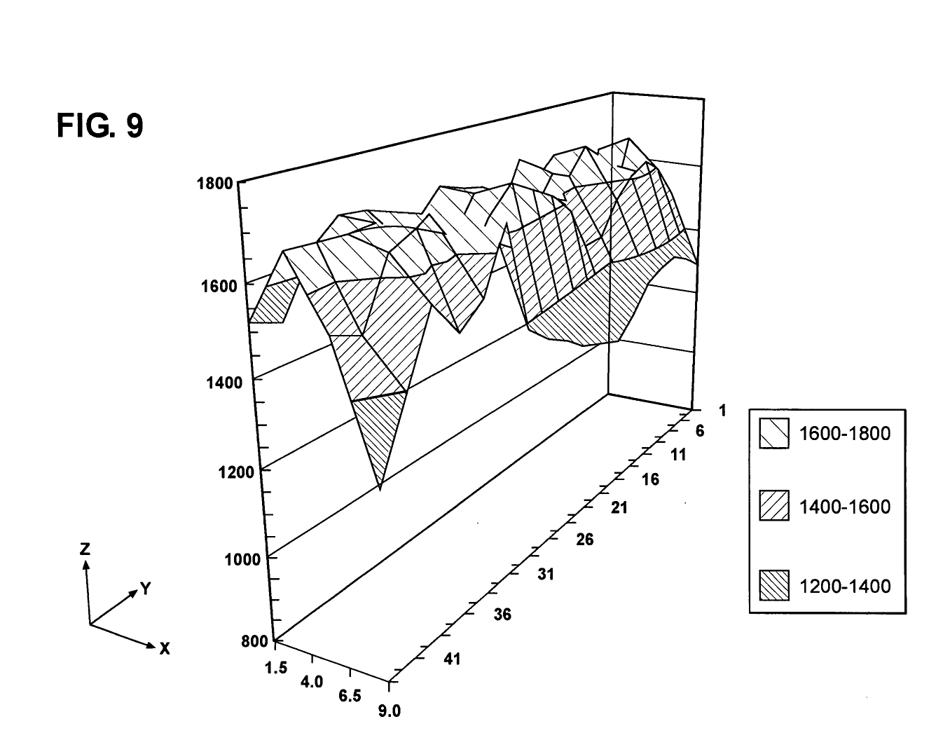

FIG. 8 illustrates the simulation of an electric field over a surface of the electrode 42 upon activation of the energy input 46. In this embodiment, the energy input 46 is VHF power with a value of 60 MHz that provides power to bars 56 and 58 accounted for in the simulated model but not illustrated. The electric field is clearly uniform over a substantial area of the planar surface of the electrode and does not exhibit the dramatic decrease in electric field intensity near the location of the energy input compared with the electric field distribution illustrated in FIG. 2 for the deposition apparatus 10 of FIG. 1. FIG. 9 is a silicon deposition plot over a substrate using the deposition apparatus of FIG. 7 at approximately 60 MHz. The x-axis in the plot is in the direction of the length of the electrode, the y-axis is in the direction of the width of the electrode, and the z-axis is in the direction of the deposited film thickness. The deposited silicon material is clearly substantially uniform over the substrate and does not exhibit the non-uniform deposition pattern shown in curve A of FIG. 5.

It is contemplated that the deposition apparatus of FIG. 7, or alternative embodiments apparent to those skilled in the art, can be utilized for depositing material over a substrate area 50 inches by 50 inches or less via the application of VHF or RF energy to the interface structure. The lengths of the slots/gaps forming the spacing between members of the interface structure or between the members and the electrode are configured for the formation an improved uniform distribution of electric field in a predetermined region between the electrode and the substrate. Alternative embodiments of the deposition apparatus 40, including configurations of the electrode and interface structure, can include the structural, shape, material, etc. options discussed hereinabove with respect to the embodiment of deposition apparatus 20 of FIG. 3. It is also intended that in the embodiments, the electrode and/or interface structure include conducting materials including the options discussed hereinabove or combinations thereof.

Of course, there are other alternative configurations of interface structure in addition to those discussed above with respect to deposition apparatus 20 and 40. For example, in one alternative embodiment the electrode of FIG. 7 is configured so that interface structure is an integral portion of the electrode. For instance, the electrode body can be machined to form the bar, cavities and slot/recessed portions to form the interface structure joined with the electrode body.

In another alternative embodiment illustrated in FIG. 10, energy is electrically coupled to the electrode 42 utilizing interface structure 64 to form a substantially uniform electric field in a predetermined region between an electrode surface the spaced apart substrate. Additionally, an alternative embodiment of the interface structure shown in FIG. 10 can be made an integral portion of the respective electrode body as described above with respect to FIG. 7.

And in another alternative embodiment of the deposition apparatus, an electrode can have a second interface structure, having a configuration of interface structure described hereinabove or an alternative thereof, that is joined with another distinct portion of the electrode for even further promoting the formation of a substantially uniform electric field about an electrode surface spaced apart from one or more substrates. In that embodiment, each of the interface structures is electrically coupled with one or more energy sources. In yet another alternative embodiment, a portion of an interface structure is adjustable (with respect to the side of the electrode or with respect to another portion of the interface structure) to relocate a bar, slot or recessed portion of the structure in a manner to more easily reconfigure the interface structure to adapt to an electrode configuration or otherwise aid in the formation of the substantially uniform electric field.

In yet other alternative exemplary embodiments of deposition apparatus, the interface structure is secured within an interior region of the electrode. Energy from the energy source is electrically coupled with the interface structure and the interface structure is configured to electrically couple the energy through and about the electrode in a manner to form a substantially uniform electric field in a predetermined region between an electrode surface and the substrate spaced apart from the electrode upon activation of the energy source. Non-limiting examples of the energy source provided to the interface structure include AC, DC, RF, VHF and microwave.

Exemplary embodiments of the interface structure include a plurality of energy outlets each of which is electrically coupled to an exterior surface of the electrode for promoting the formation of a substantially uniform electric field about the electrode. The exterior surface of the electrode is spaced apart from the substrate for the processing of material over the substrate. The interface structure is configured to electrically couple energy from the energy source through the energy outlets to the predetermined region between the electrode and the substrate. The energy outlets are configured and arranged in manner for promoting the formation of a substantially uniform electric field in a predetermined region between an electrode surface and the substrate. The predetermined region is a region where it is desirable to form substantially uniform plasma due to the interaction of the process gases with the substantially uniform electric field in that region.

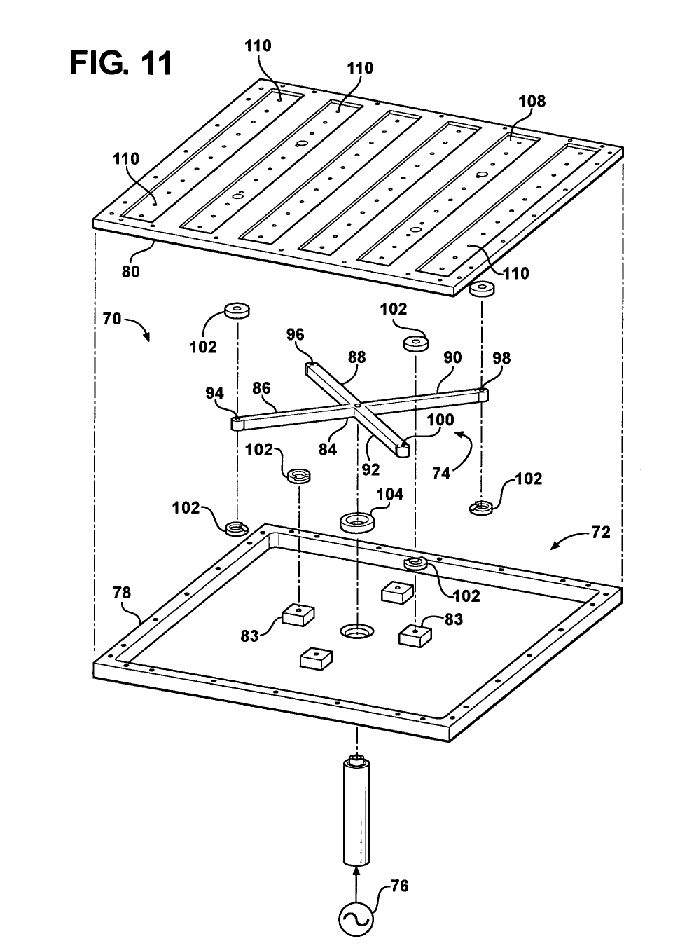

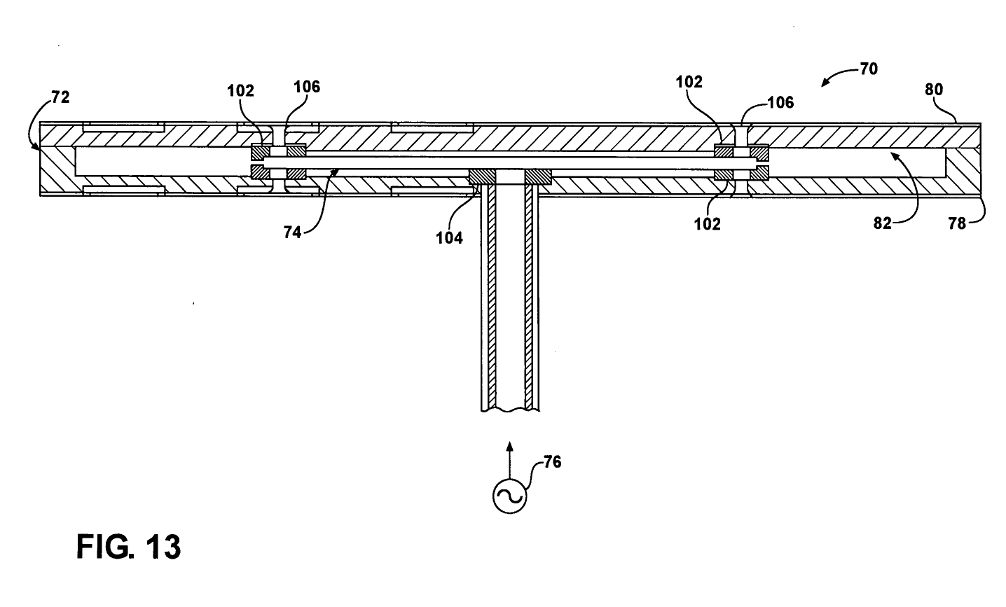

Referring to FIGS. 11-13, deposition apparatus 70 in accordance with an exemplary embodiment is illustrated. Deposition apparatus 70 includes an electrode 72, interface structure 74, and energy input 76 electrically coupled with the interface structure. The electrode 72 includes a lower cover 78 and an upper cover 80 that when joined together forming a cavity 82 therein. The cavity 82 is configured to receive the interface structure 74 therein. The deposition apparatus is configured to provide structural and electrical integrity between the lower and upper covers with respect to the interface structure therein. For example, a plurality of supports 83 are positioned and configured to support in this case the upper cover 80 while not providing a conducting path between the supports 83.

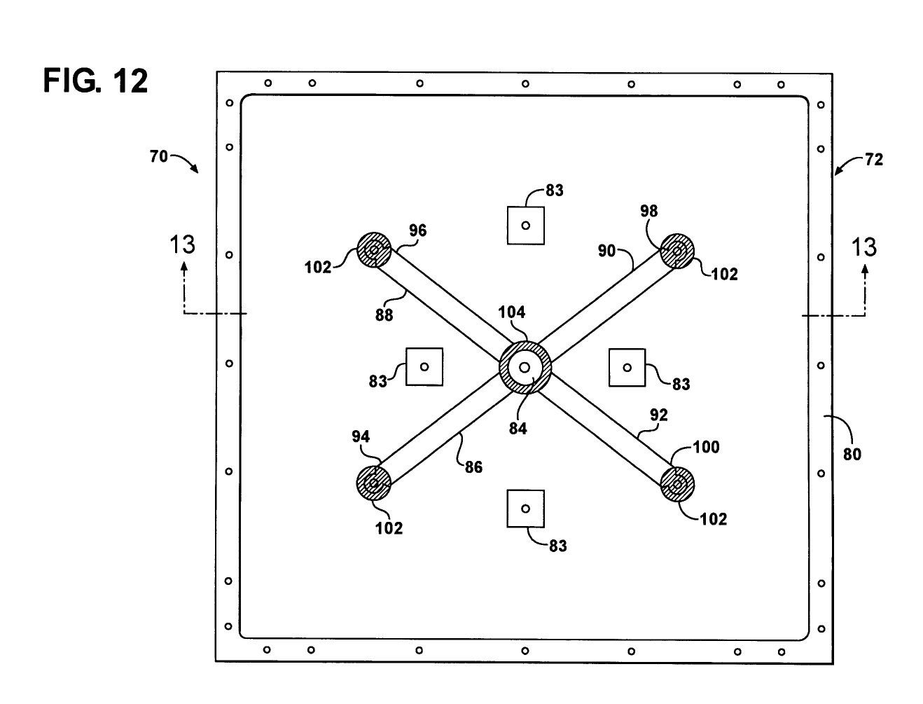

In this embodiment, the interface structure 74 includes a central portion 84, and four branches 86, 88, 90, and 92 each extending away from the central portion 84. The central portion of the interface structure is electrically coupled with the energy input 76. Each of the four branches includes an energy outlet 94, 96, 98, and 100 distal the central portion. The interface structure is configured to electrically couple the input energy from the central portion along each of the branches to each of the four energy outlets, as illustrated in FIGS. 11 and 12.

The interface structure is insulated from the lower and upper covers of the electrode by insulators 102 and 104 made of an insulating material, for example a ceramic material. The energy is electrically coupled from the energy output of each branch through a conducting member to an exterior region of the electrode. In this embodiment, the energy is directed through a stainless steel screw 106 toward an outer surface 108 of the electrode upper cover 80.

In this configuration of deposition apparatus 70, the distance from the energy input to each of the energy outputs. is substantially equal. Additionally, configurations of the deposition apparatus may include an electrode configured for receiving gas into the cavity and directing gas from the cavity of the electrode. For example, in this embodiment the upper cover 80 of the electrode includes pores 110 so gaseous materials ejected from the cavity are directed toward the uniform electric field formed about a predetermined region of the outer surface 108 of the electrode.

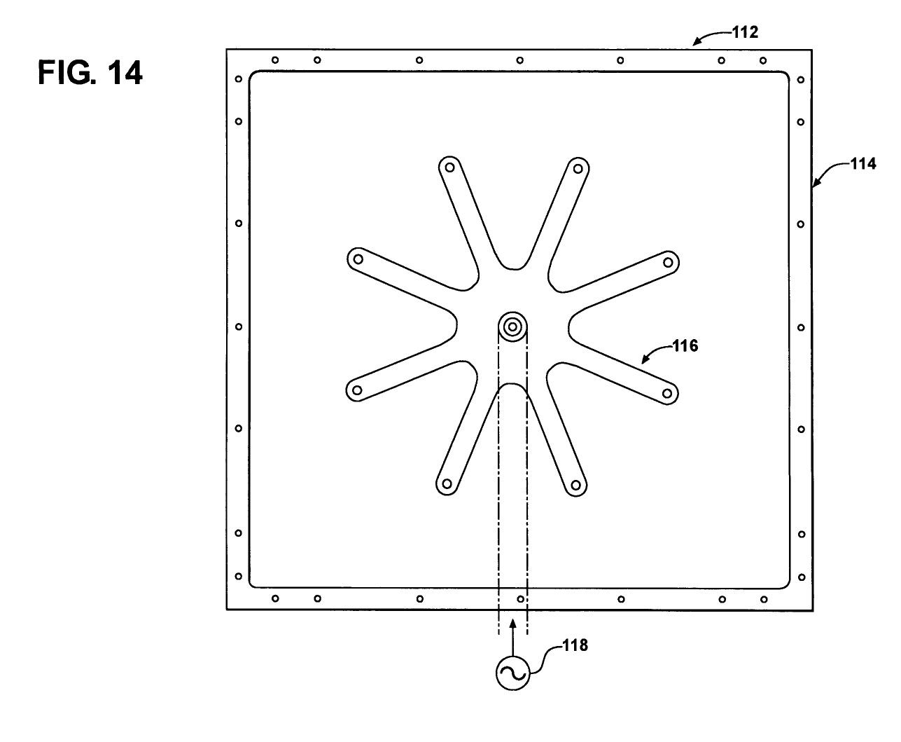

Referring to FIG. 14, deposition apparatus 112 in accordance with another alternative exemplary embodiment is illustrated. Deposition apparatus 112 includes an electrode 114, interface structure 116, and energy input 118. In this embodiment, the energy input 118 is electrically coupled with the interface structure through a side portion of the electrode 114, thereby permitting one or more substrates to be spaced apart from each of the two planar outer surfaces of the electrode. In an embodiment with one or more substrates spaced apart from each of the two sides of the electrode, the electrode can be configured to direct gases from within the cavity toward an exterior region between the respective electrode outer surface and the substrate(s). Additionally, in this embodiment, the interface structure 116 includes a greater number of branches compared to the interface structure 74 of deposition apparatus 70 in FIG. 11.

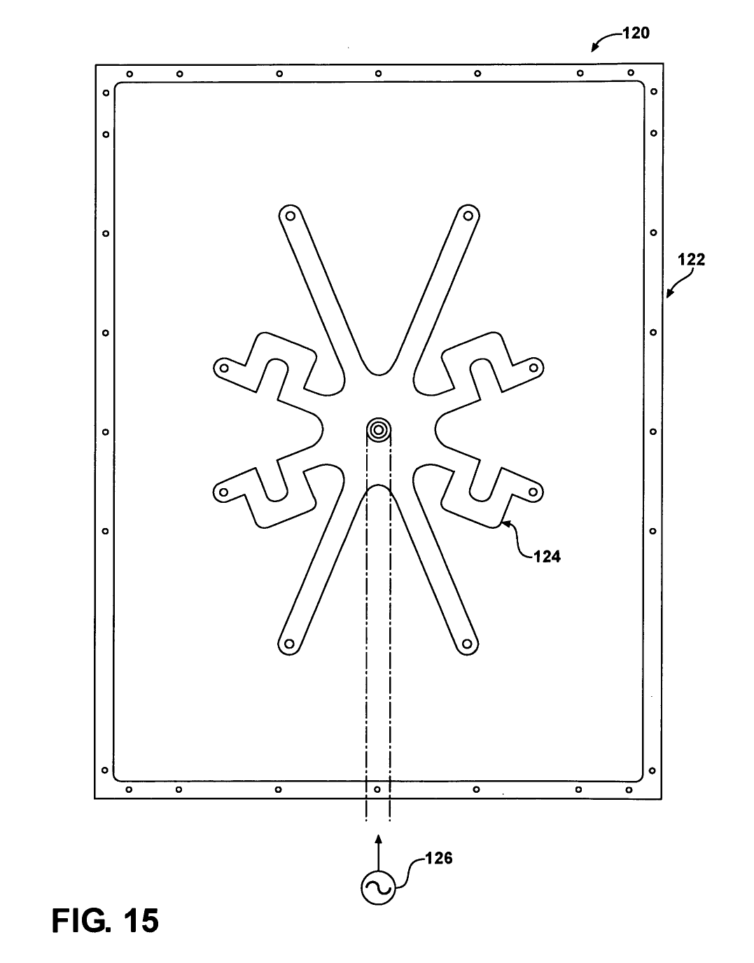

Referring to FIG. 15, deposition apparatus 120 in accordance with another alternative exemplary embodiment is illustrated. Deposition apparatus 120 includes an electrode 122, interface structure 124, and an energy input 126 where the distance from the central portion of the interface structure along each of the branches to each of the energy outputs is not equal. In another alternative embodiment, deposition apparatus 120 may include an electrode configured to eject gases from the cavity of the electrode through pores at both of the covers toward regions of uniform electric field between electrode and spaced apart substrates. Additional alternative embodiments include those where the branches are not relatively thin elongated members compared to the branches of the interface structure shown in the FIGS. 11, 14 and 15. And in another alternative embodiment, the plurality of energy outlets may be positioned anywhere about the interface structure, in electrical communication with an exterior surface of the electrode, including about the central portion, along the branches or combinations thereof.

This embodiments of deposition apparatus having the interface structure positioned with the electrode provide yet additional alternatives for electrical coupling energy from an energy source through and about the interface structure for the formation of a substantially uniform electric field about the electrode, and therefore aid in forming substantially uniform plasma in a predetermined region between the electrode and the spaced apart substrate(s).

The three embodiments of deposition apparatus 70, 112 and 120 are not intended to be limiting examples of configurations of size, shape, materials, etc. or combinations thereof. It is intended that alternative derivations are possible to those skilled in the art. The configuration of deposition apparatus will depend on the configuration of the semiconductor device being manufactured, number of substrates positioned about the electrode for processing, process involved, process gases involved, the substrate(s) horizontal, vertical or other orientation, substrate material, stationary vs. moving substrate(s), the, and/or other process parameters, etc.

The capability of forming a substantially uniform electric field contributes to forming substantially uniform plasma which in turn contributes to processing a substantially uniform material layer over a predetermined area of the substrate, for example for such processes as plasma-assisted deposition and plasma-assisted etching. Depending on the particular electrical device and material processed, uniformity can be in terms of thickness, electrical, optical, chemical property distribution, and/or compositional homogeneity. For example, for many thin film electrical devices it is highly desirable to deposit a material layer having a substantially uniform thickness and homogeneity over a predetermined area of the substrate.

It is contemplated that the exemplary embodiments of the deposition apparatus described hereinabove for promoting a substantially uniform electric field, or alternatives to those skilled in the art, can be used with additional apparatus in processes for manufacturing semiconductor devices. The additional apparatus may, for example, include various configurations of a process or reaction chamber having the electrode and substrate therein, for controlling the flow of process gases into, within and out of the chamber, apparatus for controlling chamber operating temperature and pressure, heating/cooling portions of the semiconductor device (e.g. the substrate) or other components of the deposition apparatus at various stages of manufacture, and/or apparatus to further aid in contributing to the uniformity of the material processed over the substrate. Additional examples of apparatus include valves, pumps, meters, alarms, automation components and systems for controlling the parameters above, etc. Chamber operational pressures can range from atmospheric to ranges of vacuum pressure, wherein vacuum refers to a condition of less than 10⁻² torr.

Additionally, it is intended that the exemplary embodiments of the deposition apparatus for forming a substantially uniform electric field about the electrode can be applied for processing material over a single or a plurality of stationary or moving substrates. And in another application, the deposition chamber having an embodiment of the deposition apparatus described hereinabove is a portion of a contiguous line of process equipment where one or more continuous substrates extends through the line of process equipment. In the line of process equipment one or more processes may occur simultaneously.

For example, in a roll-to-roll process line for manufacturing photovoltaic devices, one or more pay-out units dispense rolled substrate(s) into other pieces of equipment some of which may be deposition chambers utilizing deposition apparatus described hereinabove for the simultaneous deposition of materials over the continuous substrate(s). At the end of the roll-to-roll process line, one or more take-up units receive the processed continuous substrate(s). An example of a contiguous line of process equipment is described in U.S. patent application Ser. No. 11/376,997, entitled “High Throughput Deposition Apparatus with Magnetic Support,” the disclosure of which is incorporated herein by reference.

In one application utilizing one or more of the above embodiments of the deposition apparatus, an electrode is positioned within a deposition or reaction chamber with one or more substrates spaced apart from the electrode. For instance, a first substrate is spaced apart from one side of the electrode and a second substrate is spaced apart from the opposite side of the electrode, wherein a substantially uniformed electric field is formed between the electrode and a predetermined area of each of the substrates. In another instance, a first plurality of substrates is spaced apart from one side of the electrode and a second plurality of substrates is spaced apart from the opposite side of the electrode, wherein a substantially uniformed electric field is formed between the electrode and a predetermined area of each of the substrates. The substrate spacing from the electrode will vary depending on the processing application. For example, in plasma-assisted deposition of material over a substrate of a photovoltaic device the substrate spacing from the electrode may vary from approximately 0.10 inches to approximately 3.00 inches.

The uniform electric field contributes to the formation of a substantially uniform plasma region between the electrode and the predetermined area of each of the substrates. The plasma region is intended to have a uniform distribution of plasma materials therein to promote substantially uniform processing of materials of the plasma over the corresponding substrate spaced apart from the electrode.

In some applications, the substrates will be substantially parallel with the electrode and coplanar with other substrates on the same side of the electrode to promote uniformity of material processed over the substrate, although in other applications the substrates may not be parallel to the electrode or coplanar with respect to other substrates. In some applications, the substrate(s) spacing on one side of the electrode will be substantially similar to the substrate(s) spacing on the opposite side of the electrode, although in other applications the spacing of the substrates may not be the same on both sides of the electrode. Factors that may determine the spacing are the process involved, configuration of the semiconductor device, process gases involved, temperature, pressure and time associated with the process, and/or other process parameters.

In some processes, one or more of the above described embodiments of deposition apparatus may also include a shield positioned between the electrode and the substrate. The shield is positioned and configured so materials of the plasma are blocked from contacting areas of the substrate other than a predetermined area of the substrate.

In another application, the deposition apparatus can include heating apparatus for contributing thermal energy to the process. Heating energy may be desirable for sustaining energy of the plasma or otherwise promoting growth of certain desirable deposited material structure. In yet another application, the deposition apparatus can include cooling apparatus for promoting growth of a certain desirable deposited material structure.

In a processing application, energy or a power supply provides electrical or electromagnetic energy to establish and maintain plasma in the plasma region between the electrode and the continuous substrate or discrete substrate. The energy supply may be an AC power supply that introduces AC energy in the radiofrequency or microwave range, but may also be a DC power supply. The energy supplied can be in the radio frequency range of 5-30 MHz. For example, an AC power supply operating at approximately 13.56 MHz. In another application, the energy supplied operates in the VHF range of 30-300 MHz. For example, the energy supplied is supplied at approximately 60 MHz. In another application, radiofrequency (including VHF frequencies (ca. 5-100 MHz)) and microwave frequencies (ca. 100 MHz-300 GHz; e.g. 2.54 GHz) may generally be used.

Non-limiting examples of deposition processes contemplated for use with the above exemplary embodiments of deposition apparatus include plasma enhanced chemical vapor deposition (PECVD), physical vapor deposition (PVD), sputtering, vacuum deposition, and plasma-assisted etching.

It is further contemplated that exemplary embodiments of the deposition apparatus disclosed above for generating and sustaining a substantially uniform electric field can be utilized for manufacturing semiconductor devices having inorganic and organic materials.

In applications, exemplary embodiments of the deposition apparatus described hereinabove are configured to process materials of the substantially uniform plasma over small and large areas of substrates. For example, in manufacturing a semiconductor device materials of substantially uniform plasma are deposited over a predetermined rectangular substrate area approximately 50 inches by 10 inches. In another example, in manufacturing a semiconductor device materials of substantially uniform plasma are deposited over a predetermined rectangular substrate area approximately 50 inches by 30 inches.

In another application, the deposition apparatus can be configured to deposit materials of substantially uniform plasma over a predetermined area of substrates less than 400 in². In another application, the deposition apparatus can be configured to deposit materials of substantially uniform plasma over a predetermined area of substrates from 400 in² to 2000 in². And in another application, the deposition apparatus can be configured to deposit materials of substantially uniform plasma over a predetermined area of substrates from 2000 in² to 10,000 in².

Below are contemplated examples of manufacturing photovoltaic devices, where utilizing the above discussed embodiments of deposition apparatus can improve the uniformity of material layers deposited over a substrate of the photovoltaic device. It is intended that the examples hereinbelow can be extended such that the deposition apparatus can be modified if necessary for the manufacture of other semiconductor devices where formation of a substantially uniform electric field is desirable during a manufacturing process of the devices.

Photovoltaic devices capable of utilizing the above embodiments of deposition apparatus for the formation of a substantially electric field include but are not limited to tandem and triad configurations of n-p, n-i-p and p-i-n junctions having photovoltaic materials such as crystalline silicon, amorphous silicon, microcrystalline silicon, nanocrystalline silicon, polycrystalline silicon, group IV semiconductor materials including hydrogenated alloys of silicon and/or germanium. Other photovoltaic materials include GaAs (Gallium Arsenide), CdS (Cadmium Sulfide), CdTe (Cadmium Telluride), CuInSe₂ (Copper Indium Diselenide or “CIS”), and Copper Indium Gallium Diselenide (“CIGS”).

Process gases utilized with the deposition apparatus will depend on the particular photovoltaic device configuration being manufactured and how portions of the gases interact with the applied energy in formation of the plasma of which portions thereof deposit to form a layer of the photovoltaic device. Process gases utilized in the formation of substantially uniform plasma may include chemically inert gas, a reactive gas, or a combination thereof. Process gases may include deposition precursor gases or the feed gases that react or are otherwise transformed into the reactive species for forming deposited material, doping precursors, and carrier gases such as inert or diulent gases which may or may not be incorporated into the deposited material.

For example, such photovoltaic devices having deposited amorphous microsrystalline, microcrystalline, nanocyrstalline and polycrystalline silicon, deposition precursors such as GeHe₃, SiH₃, SiH₂, SiH₄, SiF₄, SiH₄, Si₂H₆, and (CH₃)₂SiCl₂ may be utilized. Germaine may also be used as a deposition precursor to form germanium film or in combination with a silicon deposition precursor to form a silicon-germanium alloy. Deposition precursors may also include CH₄ and CO₂ and be combined with, for example silicon to form SiC or other carbon containing films. Deposition precursors may also include doping precursors such as phosphine, diobrane, or BF₃ for n or p type doping.

The process gases may include carrier gases such as inert or diluent gases including hydrogen, which may or may not be incorporated with the deposited materials. For example, in a-Si:H and/or a-SiGe:H film growth precursor species such as GeH₃ and/or SiH₃ are deposited over the substrate. In some applications, the process gases can include material that promotes the optimization of deposited material having reduced density of band gap defect states, for example, in the optimization of tetrahedrally coordinated photovoltaic quality amorphous alloy material deposition over the substrate. And in another application, the process gases can include material that promotes the deposition of highly defective material, for example, deposited material having a significant number of defects, dangling bonds, strained bonds and/or vacancies therein.

In one application of the manufacture of a photovoltaic device and where an embodiment of the deposition apparatus described above is utilized, a deposition of amorphous or microcrystalline silicon or SiGe material over a substrate of the photovoltaic device is accomplished through a plasma-assisted deposition technique such as plasma enhanced chemical vapor deposition (PECVD). The deposition apparatus promotes the formation of a uniform electric field between the electrode and the substrate and the uniform electric field contributes to the formation of a substantially uniform plasma region. In the PECVD deposition process, plasma is created in a deposition chamber in a plasma region between a grounded web or substrate and an electrode or cathode positioned in close proximity to the substrate.

While the foregoing description has been directed to certain embodiments of deposition apparatus utilizing structure electrically coupled with an electrode for the formation of a substantially uniform electric field about the electrode, the principles of this invention are applicable to other embodiments not disclosed herein. In view of the teachings presented herein, yet other modifications and variations of the invention will be apparent to those of skill in the art. The foregoing is illustrative of particular embodiments, but is not meant to be a limitation upon the practice thereof. It is the following claims, including all equivalents, which define the scope of the invention.

What is claimed is:

1. Deposition apparatus for uniformly processing material over a substrate, the deposition apparatus comprising:
an energy source;
an electrode in a facing, spaced relationship with respect to the substrate; and
interface structure joined to the electrode, the interface structure being configured to electrically couple energy from the energy source through and about the interface structure to the electrode for formation of a substantially uniform electric field between the electrode and a predetermined area of the substrate when the interface structure is supplied with energy from the energy source.

2. The deposition apparatus of claim 1, wherein electrically coupling the energy includes distributively coupling the energy along a substantial dimension of the interface structure contiguous with the electrode.

3. The deposition apparatus of claim 1, wherein the interface structure comprises a plurality of different regions and at least two of the regions at least partially overlap one another.

4. The deposition apparatus of claim 3, wherein the interface structure includes a bar joined to the electrode such that a slot is formed between the electrode and the bar.

5. The deposition apparatus of claim 3, wherein the interface structure is an integral portion of the electrode.

6. The deposition apparatus of claim 3, further comprising a reaction chamber configured to receive the substrate, the electrode and the interface structure therein.

7. The deposition apparatus of claim 6, wherein the substrate is electrically grounded within the reaction chamber.

8. The deposition apparatus of claim 6, wherein at least a portion of the substrate is heated.

9. The deposition apparatus of claim 6, wherein the substrate moves across the substantially uniform electric field.

10. The deposition apparatus of claim 6, wherein the electrode is spaced apart from the substrate from approximately 0.10 inches to approximately 3.00 inches in a predetermined deposition area.

11. The deposition apparatus of claim 6, wherein the substrate is electrically grounded, at least a portion of the substrate is heated, the substrate moves across the substantially uniform electric field, the electrode is spaced apart from the substrate from approximately 0.10 inches to approximately 3.00 inches, and the energy source provides RF energy having a value of approximately 13.56 MHz.

12. The deposition apparatus of claim 11, further comprising a shield positioned between a portion of the electrode and the substrate.

13. The deposition apparatus of claim 6, wherein the predetermined area of the substrate positioned within the substantially uniform electric field is less than or equal to 400 cm².

14. The deposition apparatus of claim 6, wherein the predetermined area of the substrate positioned within the substantially uniform electric field is greater than 400 in² and less than or equal to 1000 in².

15. The deposition apparatus of claim 6, wherein the predetermined area of the substrate positioned within the substantially uniform electric field is greater than 1000 in² and less than or equal to 10,000 in².

16. The deposition apparatus of claim 1, wherein the interface structure comprises a first interface structure and a second interface structure, the first interface structure joined to a first side of the electrode, the second interface structure joined to a second side of the electrode, the first and a second interface structures being configured to electrically couple energy from the energy source through and about each of the first and second interface structures to the electrode for promoting formation of a substantially uniform electric field between the electrode and the predetermined area of the substrate.

17. The deposition apparatus of claim 16, wherein the energy source comprises a first energy source and a second energy source, the first energy source providing first energy to the first interface structure, the second energy source providing second energy to the second interface structure.

18. The deposition apparatus of claim 1, wherein the energy source comprises two energy sources, each of the two energy sources being electrically coupled to a different portion of the interface structure.

19. The deposition apparatus of claim 1, wherein the energy source provides RF energy.

20. The deposition apparatus of claim 1, wherein the energy source provides VHF energy.

21. The deposition apparatus of claim 1, wherein the interface structure comprises a plurality of different regions positioned along a side of the electrode and spaced apart from each other in an outward direction from the side of the electrode, and at least two of the regions at least partially overlap one another.

22. The deposition apparatus of claim 21, wherein the spacing between a member of the interface structure and the electrode or the space between two members of the interface structure is up to 10× a cross sectional thickness of one of the members.

23. The deposition apparatus of claim 21, wherein at least one of the regions has an adjustable position.

24. The deposition apparatus of claim 21, wherein the energy source is RF energy having a value in the range of approximately 10 MHz to approximately 30 MHz.

25. The deposition apparatus of claim 21, wherein the energy source is VHF energy having a value in the range of approximately 30 MHz to approximately 100 MHz.

26. A plasma-assisted deposition system utilizing the apparatus of claim 1.

27. A plasma-assisted etching system utilizing the apparatus of claim 1.

28. A photovoltaic device made in part utilizing the apparatus of claim 1.

29. The photovoltaic device of claim 28, wherein a layer of the device is deposited over the substrate of the device during a plasma-assisted deposition process.

30. Deposition apparatus for uniformly processing material over a substrate, the deposition apparatus comprising:
an energy source;
a plurality of substrates comprising a first substrate and a second substrate in a facing, spaced relationship with respect to each other;
an electrode positioned between the first and the second substrates, the electrode being in a facing, spaced relationship with respect to both the first and the second substrates;
interface structure joined to the electrode, the interface structure being configured to electrically couple energy from the energy source through and about the interface structure to the electrode for the formation of a substantially uniform electric field between the electrode and a predetermined area of the first substrate and between the electrode and a predetermined area of the second substrate when the interface structure is supplied with energy from the energy source;
a reaction chamber configured to receive the first and second substrates, the electrode and the interface structure therein; and
apparatus configured to distribute the inlet of gaseous materials into the reaction chamber and the outlet of gaseous materials from the reaction chamber.

31. The deposition apparatus of claim 30, wherein the interface structure comprises a plurality of different regions and at least two of the regions at least partially overlap one another.

32. The deposition apparatus of claim 31, wherein the interface structure includes a combination of materials.

33. The deposition apparatus of claim 30, wherein the energy source comprises two energy sources, each of the two energy sources being electrically coupled to a different portion of the interface structure.

34. The deposition apparatus of claim 30, wherein each of the first and second substrates is electrically grounded, at least a portion of each of the first and second substrates is heated, each of the first and second substrates move across the substantially uniform electric field between the electrode and the first substrate and between the electrode and the second substrate, and the electrode is spaced apart from each of the first and second substrates from approximately 0.10 inches to approximately 3.00 inches.

35. The deposition apparatus of claim 34, further comprising a shield positioned between at least one of the first or second substrates and the electrode.

36. The deposition apparatus of claim 30, wherein the plurality of substrates comprises a first plurality of substrates and a second plurality of substrates, each of the first and second plurality of substrates having a facing, spaced relationship with respect to the electrode, the first plurality of substrates being positioned in a spaced, coplanar manner with respect to each other on one side of the electrode, the second plurality of substrates being positioned in a spaced, coplanar manner with respect to each other on the other side of the electrode, and the interface structure is configured to electrically couple energy from the energy source through and about the interface structure to the electrode for forming a substantially uniform electric field between the electrode and a predetermined area of the first plurality of substrates and between the electrode and a predetermined area of the second plurality of substrates when the interface structure is supplied with energy from the energy source.

37. The deposition apparatus of claim 36, wherein the energy source provides RF energy having a value of approximately 13.56 MHz.

38. The deposition apparatus of claim 36, wherein the energy source provides VHF energy having a value in the range of approximately 30 MHz to approximately 100 MHz.

39. The deposition apparatus of claim 1, wherein the electrode includes a cavity configured to receive the interface structure securely therein, and the interface structure includes a plurality of energy outlets electrically coupled with an exterior surface of the electrode spaced apart from the substrate, whererin the interface structure is configured to electrically couple energy from the energy source through and about the interface structure to the energy outlets for formation of a substantially uniform electric field between the exterior surface of the electrode and a predetermined area of the substrate when the interface structure is supplied with energy from the energy source.

40. The deposition apparatus of claim 38, wherein the interface structure further comprises a central portion electrically coupled with the energy source and each of the plurality of energy outlets.

41. The deposition apparatus of claim 40, wherein the interface structure further includes a plurality of spaced apart branches, each branch having one or more of the plurality of energy outlets.

42. The deposition apparatus of claim 39, wherein the energy source electrically couples to the interface structure through a portion of the electrode that is not between the exterior surface of the electrode and the substrate.

43. The deposition apparatus of claim 42, wherein the energy source electrically couples to the interface structure through a side portion of the electrode.

44. The deposition apparatus of claim 39, wherein the electrode is further configured to receive gas within the cavity and direct gas from the cavity toward the uniform field between the exterior surface of the electrode and the substrate.

45. The deposition apparatus of claim 39, wherein the electrode and the interface structure are configured so the interface structure includes a first plurality of energy outlets electrically coupled with a first exterior surface of the electrode and a second plurality of energy outlets electrically coupled with a second exterior surface of the electrode, the interface structure being configured to electrically couple energy from the energy source through and about the interface structure to each of the plurality of energy outlets for formation of a substantially uniform electric field between the first exterior surface of the electrode and a first substrate spaced apart from the first exterior surface and formation of a substantially uniform electric field between the second exterior surface of the electrode and a second substrate spaced apart from the second exterior surface when the interface structure is supplied with energy from the energy source.

46. The deposition apparatus of claim 45, wherein the electrode is further configured to receive gas within the cavity and direct gas from the cavity toward the uniform field between the first exterior surface and the first substrate and between the second exterior surface and the second substrate.

47. The deposition apparatus of claim 39, wherein the energy source provides RF energy having a value in the range of approximately 10 MHz to approximately 30 MHz.

48. The deposition apparatus of claim 39, wherein the energy source provides VHF energy having a value in the range of approximately 30 MHz to approximately 100 MHz.

49. A method of processing material over a substrate, the method comprising:
providing a reaction chamber, an electrode facing and spaced apart from the substrate, an interface structure joined to the electrode; and an energy source, the reaction chamber configured to receive the substrate, the electrode and the interface structure therein, and the interface structure being configured to electrically couple energy from the energy source through and about the interface structure to the electrode for the formation of a substantially uniform electric field between the electrode and a predetermined area of the substrate when energy from the energy source is supplied to the interface structure;
supplying a gas into the reaction chamber;
setting a pressure within the reaction chamber at a vacuum pressure;
supplying energy from the energy source to the interface structure; and
forming a plasma within the substantially uniform electric field, wherein a material of the plasma is deposited on the substrate.

50. The method of claim 49, wherein the interface structure comprises a plurality of different regions and at least two of the regions at least partially overlap one another.

51. The method of claim 50, wherein the deposited material has substantially uniform thickness in the predetermined area of the substrate.
